(19) United States
(12) Patent Application Publication
(10) Pub. No.: US 2013/0061928 A1
(43) Pub. Date: Mar. 14, 2013

(54) ORGANIC SOLAR CELL AND METHOD OF MANUFACTURING THE SAME

(71) Applicants: Sung Young Yun, Suwon-si (KR); Yeong Suk Choi, Suwon-si (KR); Soo-Ghang Ihn, Hwaseong-si (KR); Bulliard Xavier, Suwon-si (KR); Youn Hee Lim, Seoul (KR); In Sun Park, Seoul (KR); Yeon Ji Chung, Seoul (KR)

(72) Inventors: Sung Young Yun, Suwon-si (KR); Yeong Suk Choi, Suwon-si (KR); Soo-Ghang Ihn, Hwaseong-si (KR); Bulliard Xavier, Suwon-si (KR); Youn Hee Lim, Seoul (KR); In Sun Park, Seoul (KR); Yeon Ji Chung, Seoul (KR)

(73) Assignee: SAMSUNG ELECTRONICS CO., LTD., Suwon-si (KR)

(21) Appl. No.: 13/371,933

(22) Filed: Feb. 13, 2012

(30) Foreign Application Priority Data
Sep. 14, 2011 (KR) 10-2011-0092539

(51) Int. Cl. H01L 51/46; H01L 51/48

(52) U.S. Cl. 136/263; 438/82; 257/E51.026

(57) ABSTRACT

According to example embodiments, an organic solar cell includes a first electrode, a second electrode on the first electrode, and a photoactive layer between the first electrode and the second electrode. The photoactive layer includes a photoactive material and an ultraviolet (UV) absorber. The ultraviolet (UV) absorber may be represented by Chemical Formula 1, disclosed herein.

### CROSS-REFERENCE TO RELATED APPLICATION

This application claims priority under 35 U.S.C. §119 to Korean Patent Application No. 10-2011-0092539 filed in the Korean Intellectual Property Office on Sep. 14, 2011, the entire contents of which are incorporated herein by reference.

### BACKGROUND

1. Field

Example embodiments relate to an organic solar cell and a method of manufacturing the same.

2. Description of the Related Art

A solar cell is a photoelectric conversion device that may transform solar and/or light energy into electrical energy. Solar cells are attracting attention as an energy source.

A solar cell may include p-type and n-type semiconductors. A solar cell may produce electrical energy by collecting electrons and holes in each electrode when an electron-hole pair (EHP) is produced by solar and/or light energy absorbed in a photoactive layer containing the p-type and n-type semiconductors.

A solar cell may be classified as an organic solar cell or an inorganic solar cell, based on the materials of the photoactive layer. The organic solar cell may be a bi-layer p-n junction structure in which a p-type semiconductor is formed in a separate layer from an n-type semiconductor, and a bulk heterojunction structure in which a p-type semiconductor is mixed with an n-type semiconductor.

### SUMMARY

Example embodiments relate to an organic solar cell and a method of manufacturing the same.

According to example embodiments, an organic solar cell includes a photoactive layer.

Organic solar cells according to example embodiments may have desired morphology characteristics and may improve at least one of the light absorption rate, short circuit current density (J_{SC}), fill factor (FF), efficiency and life-span characteristics of the solar cell.

According to example embodiments, an organic solar cell includes a first electrode, a second electrode on the first electrode, and a photoactive layer between the first electrode and the second electrode. The photoactive layer includes a photoactive material and an ultraviolet (UV) absorber.

The ultraviolet (UV) absorber may absorb light having a wavelength of about 100 nm to about 400 nm, and the ultraviolet (UV) absorber may emit light having a wavelength of about 150 nm to about 500 nm.

The ultraviolet (UV) absorber may absorb light having a wavelength of about 200 nm to about 330 nm, and the ultraviolet (UV) absorber may emit light having a wavelength of about 320 nm to about 450 nm.

The ultraviolet (UV) absorber may absorb light having a wavelength of about 250 nm to about 325 nm, and the ultraviolet (UV) absorber may emit light having a wavelength of about 320 nm to about 450 nm.

The ultraviolet (UV) absorber may include a compound represented by the following Chemical Formula 1:

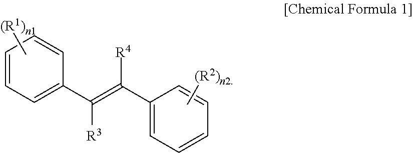

In Chemical Formula 1, R¹ to R⁴ may be the same or different, and may each independently be one of hydrogen, a substituted or unsubstituted C1 to C30 alkyl group, a substituted or unsubstituted C3 to C30 cycloalkyl group, or a substituted or unsubstituted C2 to C30 heterocycloalkyl group, R¹ to R⁴ may be the same or different, and are each independently hydrogen, a substituted or unsubstituted C1 to C10 alkyl group, a substituted or unsubstituted C3 to C10 cycloalkyl group, or a substituted or unsubstituted C2 to C10 heterocycloalkyl group, and n1 and n2 are each independently an integer ranging from 0 to 5.

In Chemical Formula 1 above, R¹ to R⁴ may be the same or different, and may each independently be one of a hydrogen, a substituted or unsubstituted C1 to C10 alkyl group, a substituted or unsubstituted C3 to C10 cycloalkyl group, and a substituted or unsubstituted C2 to C10 heterocycloalkyl group.

The ultraviolet (UV) absorber may include a compound represented by the following Chemical Formula 1-1:

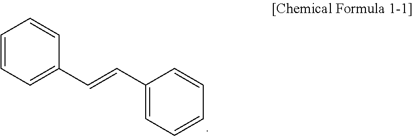 [SMILES: C(=C\c1ccccc1)/c1ccccc1]

The photoactive layer may contain about 0.01 parts by weight to about 30 parts by weight of the ultraviolet (UV) absorber, based on 100 parts by weight of the photoactive material.

The photoactive layer may contain about 0.1 parts by weight to about 10 parts by weight of the ultraviolet (UV) absorber, based on 100 parts by weight of the photoactive material.

The photoactive layer may include a bulk heterojunction (BHJ) structure.

The photoactive material may include a p-type semiconductor material and an n-type semiconductor material.

Examples of the photoactive material may include at least two of polyaniline, polypyrrole, polythiophene, poly(p-phenylenevinylene), poly(2-methoxy-5-(2′-ethyl-hexyloxy)-1,4-phenylene vinylene) (MEH-PPV), poly(2-methoxy-5-(3,7-dimethyloctyloxy)-1,4-phenylene-vinylene) (MDMO-PPV), pentacene, poly(3,4-ethylenedioxythiophene) (PEDOT), poly(3-alkylthiophene), poly((4,8-bis(octyloxy)benzo(1,2-b:4,5-b′)dithiophene-2,6-diyl)(2-((dodecyloxy)carbon yl)thieno(3,4-b)thiophenediyl)) (PTB1), poly((4,8-bis(2-ethylhexyloxy)benzo(1,2-b:4,5-b′)dithiophene-2,6-diyl)(2-((2-ethylhexy loxy)carbonyl)-3-fluorothieno(3,4-b)thiophenediyl)) (PTB7), phthalocyanine, tin (II) phthalocyanine (SnPc), copper phthalocyanine, triarylamine, bezidine, pyrazoline, styrylamine, hydrazone, carbazole, thiophene, 3,4-ethylenedioxythiophene (EDOT), pyrrole, phenanthrene, tetracene, naphthalene, rubrene, 1,4,5,8-naphthalene-tetracarboxylic dianhydride (NTCDA), Alq₃, fullerene (C60, C70, C74, C76, C78, C82, C84, C720, C860, and the like), 1-(3-methoxy-carbonyl)propyl-1-phenyl(6,6)C61 (PCBM), C71-PCBM, C84-PCBM, bis-PCBM, perylene, CdS, CdTe, CdSe, ZnO, a derivative thereof, and a combination thereof.

A solvent for providing the photoactive layer may include one of deionized water, methanol, ethanol, propanol, 1-butanol, isopropanol, 2-methoxyethanol, 2-ethoxyethanol, 2-propoxyethanol 2-butoxyethanol, methylcellosolve, ethylcellosolve, diethylene glycol methylether, diethylene glycol ethylether, dipropylene glycol methylether, toluene, xylene, hexane, heptane, octane, ethylacetate, butylacetate, diethylene glycol dimethylether, diethylene glycol dimethylethylether, methylmethoxy propionate, ethylethoxy propionate, ethyl lactate, propylene glycol methyletheracetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide (DMF), N,N-dimethyl acetamide (DMAc), N-methyl-2-pyrrolidone, γ-butyrolactone, diethylether, ethylene glycol dimethylether, diglyme, tetrahydrofuran, chlorobenzene, dichlorobenzene, acetylacetone, acetonitrile, bromobenzene, 1-chloronaphthalene, fluorobenzene, 1,2,4-trichlorobenzene, 2-bromothiophene, benzaldehyde, acetophenone, ethylene dichloride, 1,1,2,2-tetrachloroethane, iodobenzene, 1-bromonaphthalene, nitrobenzene, pyridine, di-(2-chloroethyl)ether, benzyl acetate, cyclohexyl chloride, tetrahydronaphthalene, 1-iodonaphthalene, cyclohexanone, 1,1,2-trichloroethane, trichloroethylene, 2-chlorothiophene, 1,1,1-trichloroethane, styrene, diethyl sulfide, methylene diiodide, 1,1,2,2-tetrabromoethane, 1-chlorobutane, ethyl benzene, butanethiol, benzene, thiophene, methylene dichloride, 1,4-dioxane, cyclohexylamine, furan, carbon tetrachloride, tetrahydrofuran, N-methylpyrrolidine, methyl ethyl ketone, methyl isobutyl ketone, cyclohexane, 2-nitropropane, and a combination thereof.

The photoactive material and the ultraviolet (UV) absorber may have a radius of interaction (Rₐ) of about 7 or less.

The photoactive material and the ultraviolet (UV) absorber may have a radius of interaction (Rₐ) of about 5 or less.

The photoactive material may include C71-PCBM and one of PTB1 and PTB7. The ultraviolet absorber may include a compound represented by the foregoing Chemical Formula 1.

The organic solar cell may include at least one of an electron transporting layer (ETL) and a hole transporting layer (HTL) between the photoactive layer and one of the first electrode and the second electrode. The ultraviolet absorber may include a compound represented by the foregoing Chemical Formula 1.

The photoactive layer may include one of a bi-layer structure, a multi-junction structure, and a bulk heterojunction structure.

According to example embodiments, a solar cell module may include a plurality of the foregoing organic solar cells, and the organic solar cells may be electrically connected to each other in one of series, parallel, and series-parallel.

According to example embodiments, a method of manufacturing an organic solar cell includes forming a photoactive layer on one surface of a first electrode, the photoactive layer including a photoactive material and an ultraviolet (UV) absorber, and forming a second electrode on the photoactive layer.

The forming a photoactive layer may include mixing a photoactive material, an ultraviolet (UV) absorber, and a solvent to provide a mixture, and coating the mixture on the one surface of the first electrode.

Unless otherwise described hereinafter, the first electrode, the photoactive layer, the second electrode, the photoactive material, the ultraviolet (UV) absorber, and the solvent are the same as above.

The photoactive material and the ultraviolet (UV) absorber may have a radius of interaction (Rₐ) of about 7 or less.

### BRIEF DESCRIPTION OF THE DRAWINGS

The foregoing and other features and advantages of example embodiments will be apparent from the more particular description of non-limiting embodiments, as illustrated in the accompanying drawings in which like reference characters refer to the same parts throughout the different views. The drawings are not necessarily to scale, emphasis instead being placed upon illustrating the principles of example embodiments. In the drawings:

FIG. 1 is a cross-sectional view of an organic solar cell according to example embodiments.

FIG. 2 is a graph showing light absorption wavelength and emission wavelength of the compound represented by Chemical Formula 1-1 used in Examples 1 to 4.

FIG. 3 is a TEM image of the photoactive layer obtained from Example 1.

FIG. 4 is a TEM image of the photoactive layer obtained from Comparative Example 1.

FIG. 5 shows an I-V curve for the organic solar cells according to Example 1 and Comparative Example 1.

FIG. 6 shows an I-V curve for the organic solar cells according to Examples 2 to 4 and Comparative Example 2.

FIGS. 7A to 7D, respectively, show cross-sectional views of solar cells according to example embodiments.

FIGS. 7E to 7F, respectively, show cross-sectional views of solar modules according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scopes of example embodiments of inventive concepts to those of ordinary skill in the art.

As used herein, when a specific definition is not otherwise provided, the term “substituted” refers to one substituted with at least one substituent selected from a halogen (—F, —Cl, —Br, or —I), a hydroxy group, a nitro group, a cyano group, an amino group (NH₂, NH(R²⁰⁰), or N(R²⁰¹)(R²⁰²), wherein R²⁰⁰, R²⁰¹, and R²⁰² are the same or different, and are each independently a C1 to C10 alkyl group), an amidino group, a hydrazine group, a hydrazone group, a carboxyl group, a substituted or unsubstituted alkyl group, a substituted or unsubstituted haloalkyl group, a substituted or unsubstituted alkoxy group, and a substituted or unsubstituted heterocycloalkyl group in place of at least one hydrogen of a functional group.

As used herein, when a specific definition is not otherwise provided, the term “alkyl group” may refer to a C1 to C30 alkyl group, specifically a C1 to C20 alkyl group, and more specifically a C1 to C10 alkyl group, the term “cycloalkyl group” may refer to a C3 to C30 cycloalkyl group, specifically a C3 to C20 cycloalkyl group, and more specifically a C3 to C10 cycloalkyl group, the term “heterocycloalkyl group” may refer to a C2 to C30 heterocycloalkyl group, specifically a C2 to C20 heterocycloalkyl group, and more specifically a C2 to C10 heterocycloalkyl group, and the term “alkoxy group” may refer to a C1 to C20 alkoxy group, specifically a C1 to C15 alkoxy group, and more specifically a C1 to C10 alkoxy group.

As used herein, when a specific definition is not otherwise provided, the term “heterocycloalkyl group” may refer to a cycloalkyl group including one to three heteroatoms of N, O, S, Si, or P and a remaining carbon in one cycle.

As used herein, when a definition is not otherwise provided, “combination” commonly refers to mixing or copolymerization. Herein, “copolymerization” refers to block copolymerization, random copolymerization, or graft copolymerization, and “copolymer” may refer to a block copolymer, a random copolymer, or a graft copolymer.

In the drawings, the thickness of layers, films, panels, regions, etc., are exaggerated for clarity. Like reference numerals designate like elements throughout the specification, thus their description may be omitted.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Other words used to describe the relationship between elements or layers should be interpreted in a like fashion (e.g., “between” versus “directly between,” “adjacent” versus “directly adjacent,” “connected” versus “directly connected,” “coupled” versus “directly coupled”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

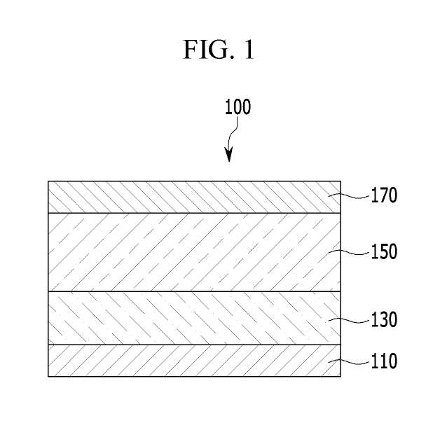

FIG. 1 is a cross-sectional view of an organic solar cell according to example embodiments.

Referring to FIG. 1, an organic solar cell 100 according to example embodiments may include a substrate 110, a lower electrode 130 on one surface of the substrate 110, a photoactive layer 150 on one surface of the lower electrode 130, and an upper electrode 170 on one surface of the photoactive layer 150. The photoactive layer 150 includes a photoactive material and an ultraviolet (UV) absorber

The substrate 110 may contain a light-transmitting material, for example, an inorganic material such as glass or an organic material such as polycarbonate, polymethylmethacrylate, polyethylene terephthalate, polyethylene naphthalate, polyamide, and polyethersulfone, but example embodiments are not limited thereto.

One of the lower electrode 130 and the upper electrode 170 is an anode, while the other is a cathode. At least one of the lower electrode 130 and the upper electrode 140 may be include a transparent conductor such as one of indium tin oxide (ITO), indium-doped zinc oxide (IZO), aluminum-doped ZnO (AZO), gallium-doped ZnO (GZO), antimony-doped tin oxide (ATO), fluorine-doped tin oxide (FTO), tin oxide (SnO₂), ZnO, TiO₂, and combinations thereof, but example embodiments are not limited thereto. The other of the lower electrode 130 and the upper electrode 170 may include an opaque conductor such as aluminum (Al), copper (Cu), titanium (Ti), gold (Au), platinum (Pt), silver (Ag), chromium (Cr), lithium (Li), calcium (Ca), and a combination thereof, but example embodiments are not limited thereto. Alternatively, both of the lower electrode 130 and the upper electrode 170 may include a transparent conductor. Each of the lower electrode 130 and the upper electrode 170 may independently include a single layer or multiple layers.

The photoactive material of the photoactive layer 150 may include an electron acceptor containing an n-type semiconductor material and an electron donor containing a p-type semiconductor material. The photoactive layer 150 may have a bulk heterojunction (BHJ) structure, but example embodiments are not limited thereto.

In the bulk heterojunction (BHJ) structure, when electron-hole pairs excited by the light absorbed in the photoactive layer 150 reach the interface of the electron acceptor and electron donor through diffusion, electrons and holes are separated by the affinity difference of two materials forming the interface. Electrons are transported to the cathode through the electron acceptor while holes are transported to the anode through the electron donor to generate a photocurrent.

The photoactive material may include at least two selected from polyaniline, polypyrrole, polythiophene, poly(p-phenylenevinylene), poly(2-methoxy-5-(2′-ethyl-hexyloxy)-1,4-phenylene vinylene) (MEH-PPV), poly(2-methoxy-5-(3,7-dimethyloctyloxy)-1,4-phenylene-vinylene) (MDMO-PPV), pentacene, poly(3,4-ethylenedioxythiophene) (PEDOT), poly(3-alkylthiophene), poly((4,8-bis(octyloxy)benzo(1,2-b:4,5-b′)dithiophene-2,6-diyl)(2-((dodecyloxy)carbon yl)thieno(3,4-b)thiophenediyl)) (PTB1), poly((4,8-bis(2-ethylhexyloxy)benzo(1,2-b:4,5-b′)dithiophene-2,6-diyl)(2-((2-ethylhexy loxy)carbonyl)-3-fluorothieno(3,4-b)thiophenediyl)) (PTB7), phthalocyanine, tin (II) phthalocyanine (SnPc), copper phthalocyanine, triarylamine, bezidine, pyrazoline, styrylamine, hydrazone, carbazole, thiophene, 3,4-ethylenedioxythiophene (EDOT), pyrrole, phenanthrene, tetracene, naphthalene, rubrene, 1,4,5,8-naphthalene-tetracarboxylic dianhydride (NTCDA), Alq₃, fullerene (C60, C70, C74, C76, C78, C82, C84, C720, C860, and the like), 1-(3-methoxy-carbonyl)propyl-1-phenyl(6,6)C61 (PCBM), C71-PCBM, C84-PCBM, bis-PCBM, perylene, CdS, CdTe, CdSe, ZnO, a derivative thereof, and a combination thereof, but example embodiments are not limited thereto. When the bulk heterojunction includes materials having different energy levels, the n-type semiconductor may include a material having a relatively low lowest unoccupied molecular orbital (LUMO) level, and the p-type semiconductor may include a material having a relatively high LUMO level.

Since the photoactive layer 150 includes an ultraviolet (UV) absorber, the ultraviolet (UV) absorber may absorb ultraviolet (UV) light to improve light the absorption rate and may reduce (and/or prevent) degradation of the photoactive material due to ultraviolet (UV) light. Thereby, at least one of the short circuit current density (J_{SC}), the fill factor (FF), the efficiency, and the life-span characteristics of an organic solar cell including the photoactive layer 150 may be improved.

The ultraviolet (UV) absorber may absorb light having a wavelength range of about 100 nm to about 400 nm and emit light having a wavelength range of about 150 nm to about 500 nm. In other words, the ultraviolet (UV) absorber may absorb light of the ultraviolet (UV) region and shift it into a longer wavelength and emit light of the visible ray region. Thereby, the amount of light that is capable of being used for photoelectric conversion may increase and the amount of ultraviolet (UV) light that deteriorates the photoactive material may decrease. As a result, at least one of the short circuit current density (J_{SC}), the fill factor (FF), the efficiency, and the life-span characteristics of an organic solar cell including the photoactive layer 150 may improve. For example, the ultraviolet (UV) absorber may absorb light having a wavelength range of about 200 nm to about 330 nm and emit light having a wavelength range of about 320 nm to about 450 nm. For example, the ultraviolet (UV) absorber may absorb light having a wavelength range of about 250 nm to about 325 nm and emit light having a wavelength range of about 320 nm to about 450 nm.

The ultraviolet (UV) absorber may include a compound represented by the following Chemical Formula 1, but example embodiments are not limited thereto.

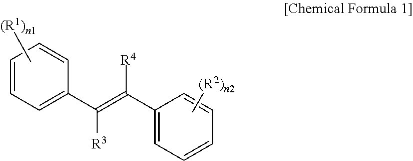

In Chemical Formula 1,

R¹ to R⁴ may be the same or different, and may each independently be one of hydrogen, a substituted or unsubstituted C1 to C30 alkyl group, a substituted or unsubstituted C3 to C30 cycloalkyl group, or a substituted or unsubstituted C2 to C30 heterocycloalkyl group. For example, R¹ to R⁴ may be the same or different, and may each independently be one hydrogen, a substituted or unsubstituted C1 to C10 alkyl group, a substituted or unsubstituted C3 to C10 cycloalkyl group, or a substituted or unsubstituted C2 to C10 heterocycloalkyl group, and n1 and n2 are each independently an integer ranging from 0 to 5.

For example, the ultraviolet (UV) absorber may include a compound represented by the following Chemical Formula 1-1, but example embodiments are not limited thereto.

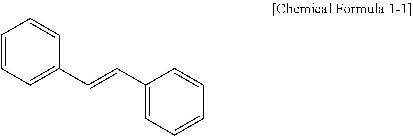 [SMILES: C(=C\c1ccccc1)/c1ccccc1]

The photoactive layer may include about 0.01 parts by weight to about 30 parts by weight of the ultraviolet (UV) absorber, based on 100 parts by weight of the photoactive material. When the photoactive layer includes about 0.01 parts by weight to about 30 parts by weight of the ultraviolet (UV) absorber, the photoactive material (e.g., pn junction) may be effectively provided in the photoactive layer and ultraviolet (UV) light may be effectively absorbed. Accordingly, at least one of the short circuit current density (J_{SC}), the fill factor (FF), the efficiency, and the life-span characteristics of the organic solar cell including the ultraviolet (UV) absorber may be effectively improved. The photoactive layer may include about 0.1 parts by weight to about 10 parts by weight of the ultraviolet (UV) absorber, based on 100 parts by weight of the photoactive material, but example embodiments are not limited thereto.

The photoactive layer 150 may be obtained by adding and mixing the photoactive material and the ultraviolet (UV) absorber into a solvent and coating the mixture.

The solvent may include one of deionized water, methanol, ethanol, propanol, 1-butanol, isopropanol, 2-methoxyethanol, 2-ethoxyethanol, 2-propoxyethanol 2-butoxyethanol, methylcellosolve, ethylcellosolve, diethylene glycol methylether, diethylene glycol ethylether, dipropylene glycol methylether, toluene, xylene, hexane, heptane, octane, ethylacetate, butylacetate, diethylene glycol dimethylether, diethylene glycol dimethylethylether, methylmethoxy propionate, ethylethoxy propionate, ethyl lactate, propylene glycol methyletheracetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide (DMF), N,N-dimethyl acetamide (DMAc), N-methyl-2-pyrrolidone, γ-butyrolactone, diethylether, ethylene glycol dimethylether, diglyme, tetrahydrofuran, chlorobenzene, dichlorobenzene, acetylacetone, acetonitrile, bromobenzene, 1-chloronaphthalene, fluorobenzene, 1,2,4-trichlorobenzene, 2-bromothiophene, benzaldehyde, acetophenone, ethylene dichloride, 1,1,2,2-tetrachloroethane, iodobenzene, 1-bromonaphthalene, nitrobenzene, pyridine, di-(2-chloroethyl)ether, benzyl acetate, cyclohexyl chloride, tetrahydronaphthalene, 1-iodonaphthalene, cyclohexanone, 1,1,2-trichloroethane, trichloroethylene, 2-chlorothiophene, 1,1,1-trichloroethane, styrene, diethyl sulfide, methylene diiodide, 1,1,2,2-tetrabromoethane, 1-chlorobutane, ethyl benzene, butanethiol, benzene, thiophene, methylene dichloride, 1,4-dioxane, cyclohexylamine, furan, carbon tetrachloride, tetrahydrofuran, N-methylpyrrolidine, methyl ethyl ketone, methyl isobutyl ketone, cyclohexane, 2-nitropropane, and a combination thereof, but example embodiments are not limited thereto.

The photoactive material and the ultraviolet (UV) absorber may have a radius of interaction (Rₐ) of about 7 or less, and about 5 or less, but example embodiments are not limited thereto.

The radius of interaction (Rₐ) between two materials refers to a coordination distance represented by Hansen parameters (δ_{di}, δₚᵢ, and δₕᵢ, wherein i indicates the material number, which is an integer greater than or equal to 1) in Hansen space and is defined as in the following Equation 1:

Rₐ=\sqrt{4(δ_{d1}−67 _{d2})²+(δₚ₁−δₚ₂)²+(δₕ₁−δₕ₂)²}. [Equation 1]

In Equation 1,

Rₐ is a radius of interaction,
δ_{d1}, δₚ₁ and δₕ₁ are Hansen parameters of a first material,
δ_{d2}, δₚ₂, and δₕ₂ are Hansen parameters of a second material, wherein one of ordinary skill in the art would appreciate that δ_{d}, δₚ, and δₕ refer to the dispersion, electrostatic, and hydrogen bond components of δ respectively.

When the photoactive material and the ultraviolet (UV) absorber have a radius of interaction within a desired value, the photoactive material and the ultraviolet (UV) absorber may be more easily mixed with each other. Thereby, the morphology of the photoactive layer 150 may be improved and at least one of the short circuit current density (J_{SC}), fill factor (FF), and efficiency of an organic solar cell 100 including the photoactive layer 150 may be improved. For example, the photoactive material and the ultraviolet (UV) absorber may have a radius of interaction (Rₐ) of about 7 or less, and about 5 or less, but example embodiments are not limited thereto.

Although not shown in FIG. 1, the organic solar cell may further include one of a hole transporting layer (HTL), an electron blocking layer (EBL), and a combination thereof between the anode and the photoactive layer.

The hole transporting layer (HTL) may facilitate the transport of holes. The hole transporting layer (HTL) may include one selected from poly (3,4-ethylenedioxythiophene):poly(styrenesulfonate) (PEDOT:PSS), biphenyltrithiophene (BP3T), polyarylamine, poly(N-vinylcarbazole), polyaniline, polypyrrole, N,N,N′,N′-tetrakis(4-methoxyphenyl)-benzidine (TPD), 4-bis[N-(1-naphthyl)-N-phenyl-amino]biphenyl (α-NPD), 4,4′,4″-Tris(N-3-methylphenyl-N-phenylamino)triphenylamine (m-MTDATA), 4,4′,4″-tris(N-carbazolyl)-triphenylamine (TCTA), and a combination thereof, but example embodiments are not limited thereto.

The electron blocking layer (EBL) may limit the transport of electrons. The electron blocking layer (EBL) may include one of poly(3,4-ethylenedioxythiophene):poly(styrenesulfonate) (PEDOT:PSS), biphenyltrithiophene (BP3T), polyarylamine, poly(N-vinylcarbazole), polyaniline, polypyrrole, N,N,N′,N′-tetrakis(4-methoxyphenyl)-benzidine (TPD), 4-bis[N-(1-naphthyl)-N-phenyl-amino]biphenyl (α-NPD), 4,4′,4″-Tris(N-3-methylphenyl-N-phenylamino)triphenylamine (m-MTDATA), 4,4′,4″-tris(N-carbazolyl)-triphenylamine (TCTA), and a combination thereof, but example embodiments are not limited thereto.

Although not shown in FIG. 1, the organic solar cell may further include one of an electron transporting layer (ETL), a hole blocking layer (HBL), and a combination thereof between the cathode and the photoactive layer.

The electron transporting layer (ETL) may facilitate the transport of electrons. The electron transporting layer (ETL) may include one of 1,4,5,8-naphthalene-tetracarboxylic dianhydride (NTCDA), bathocuproine (BCP), LiF, Alq₃, Gaq₃, Inq₃, Znq₂, Zn(BTZ)₂, BeBq₂, and a combination thereof, but example embodiments are not limited thereto.

The hole blocking layer (HBL) may limit the transport of holes and simultaneously play a role of a protective layer to limit (and/or prevent) electrical shorts The hole blocking layer (HBL) may include one of 1,4,5,8-naphthalene-tetracarboxylic dianhydride (NTCDA), bathocuproine (BCP), LiF, Alq₃, Gaq₃, Inq₃, Znq₂, Zn(BTZ)₂, BeBq₂, and a combination thereof, but example embodiments are not limited thereto.

Hereinafter, a method of manufacturing an organic solar cell according to example embodiments is described with reference to FIG. 1.

Unless otherwise mentioned, the substrate, the lower electrode, photoactive layer, the upper electrode, the photoactive material, and the ultraviolet (UV) absorber are the same as described above.

First, a lower electrode 130 is formed on a substrate 110. The lower electrode 130 may be formed by thermal evaporation, sputtering, and laminating, depending on the material for the lower electrode 130, but example embodiments are not limited thereto.

A photoactive layer 150 is formed on the lower electrode 130. The photoactive layer 150 may be formed by adding and dissolving a photoactive material and an ultraviolet (UV) absorber in a solvent to provide a mixture, coating the mixture on a lower electrode 130 according to a solution process, and drying the same, but example embodiments are not limited thereto. The solution process may include, for example, spin coating, slit coating, and Inkjet printing, but example embodiments are not limited thereto.

Unless otherwise mentioned, the solvent is the same as described above.

Then an upper electrode 170 is formed on the photoactive layer 150. The upper electrode 170 may be formed by a method, for example, of thermal evaporation, sputtering, and laminating, depending on the material for the upper electrode 170, but example embodiments are not limited thereto.

Although not shown in FIG. 1, one of a hole transporting layer (HTL), an electron blocking layer (EBL), and a combination thereof may be formed between the anode and the photoactive layer. The hole transporting layer (HTL) and the electron blocking layer (EBL) may be formed according to spin coating, slit coating, and Inkjet printing, but example embodiments are not limited thereto.

In addition, although not shown in FIG. 1, one of an electron transporting layer (ETL), a hole blocking layer (HBL), and a combination thereof may be formed between the cathode and the photoactive layer. The electron transporting layer (ETL) and the hole blocking layer (HBL) may be formed by spin coating, slit coating, and Inkjet printing, but example embodiments are not limited thereto.

Unless otherwise mentioned hereinafter, the hole transporting layer (HTL), the electron blocking layer (EBL), the electron transporting layer (ETL), and the hole blocking layer (HBL) are the same as described above.

Since the photoactive layer 150 includes the ultraviolet (UV) absorber, the organic solar cell according to example embodiments may improve at least one of the morphology of the photoactive layer 150, the short circuit current density (J_{SC}), the fill factor (FF), the efficiency, and the life-span characteristics of the organic solar cell 100 including the photoactive layer 150.

A method of manufacturing a solar cell according to example embodiments may include providing a lower electrode 130 on one surface of substrate 110, providing a photoactive layer 150 including a photoactive material and an ultraviolet (UV) absorber on one surface of the lower electrode 130, and providing an upper electrode 170 on one surface of the photoactive layer 150.

### EXAMPLES

Hereinafter, the reference is made to the following examples, but example embodiments are not limited to the following examples.

### Example 1

### Manufacture of Organic Solar Cell

Indium tin oxide (ITO) is laminated on a glass substrate and cleansed with water/ultrasonic waves and using methanol and acetone, and is treated with O₂ plasma and dried.

Then poly(3,4-ethylenedioxythiophene):poly(styrenesulfonate) (PEDOT:PSS) is coated on the ITO layer according to spin coating and dried.

A solution of which 10 mg of poly((4,8-bis(2-ethylhexyloxy)benzo(1,2-b:4,5-b′)dithiophene-2,6-diyl)(2-((2-ethylhexy loxy)carbonyl)-3-fluorothieno(3,4-b)thiophenediyl)) (PTB7), 10 mg of C71-PCBM, and 0.6 mg of a compound represented by the following Chemical Formula 1-1 are dissolved in 1 ml of chlorobenzene is coated on the PEDOT:PSS layer and dried to provide a photoactive layer.

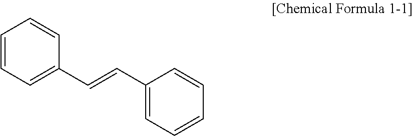 [SMILES: C(=C\c1ccccc1)/c1ccccc1]

The compound represented by Chemical Formula 1-1 and PTB7 have a radius of interaction (Rₐ) of about 4.5, and the compound represented by Chemical Formula 1-1 and C71-PCBM have a radius of interaction (Rₐ) of about 2.3.

Then Ca and Al are sequentially thermal-deposited on the photoactive layer at a deposition speed of about 5 Å/s.

Thereby, an organic solar cell is provided.

The obtained organic solar cell has a structure of ITO (150 nm)/PEDOT:PSS (30 nm)/PTB7:C71-PCBM (100 nm)/Ca (20 nm)/Al (100 nm).

### Example 2

### Manufacture of Organic Solar Cell

ITO is laminated on a glass substrate and cleansed with water/ultrasonic waves and using methanol and acetone, and treated with O₂ plasma and dried.

Then poly(3,4-ethylenedioxythiophene):poly(styrenesulfonate) (PEDOT:PSS) is coated on the ITO layer by spin coating and dried.

A solution of which 10 mg of poly((4,8-bis(octyloxy)benzo(1,2-b:4,5-b′)dithiophene-2,6-diyl)(2-((dodecyloxy)carbon yl)thieno(3,4-b)thiophenediyl)) (PTB1), 10 mg of C71-PCBM, and 0.6 mg of a compound represented by Chemical Formula 1-1 are dissolved in 1 ml of chlorobenzene is coated on the PEDOT:PSS layer and dried to provide a photoactive layer.

The compound represented by Chemical Formula 1-1 and PTB1 have a radius of interaction (Rₐ) of about 4.2, and the compound represented by Chemical Formula 1-1 and C71-PCBM have a radius of interaction (Rₐ) of about 2.3.

Then Ca and Al are sequentially thermal-deposited on the photoactive layer at a deposition speed of about 5 Å/s.

Thereby, an organic solar cell is provided.

The obtained organic solar cell has a structure of ITO (150 nm)/PEDOT:PSS (30 nm)/PTB1:C71-PCBM (100 nm)/Ca (20 nm)/Al (100 nm).

### Example 3

### Manufacture of Organic Solar Cell

An organic solar cell is fabricated in accordance with the same procedure as in Example 2, except that 1 mg of the compound represented by Chemical Formula 1-1 is used.

### Example 4

### Manufacture of Organic Solar Cell

An organic solar cell is fabricated in accordance with the same procedure as in Example 2, except that 1.4 mg of the compound represented by Chemical Formula 1-1 is used.

### Comparative Example 1

### Manufacture of Organic Solar Cell

ITO is laminated on a glass substrate and cleansed with water/ultrasonic waves and using methanol and acetone, and treated with O₂ plasma and dried.

Then poly(3,4-ethylenedioxythiophene):poly(styrenesulfonate) (PEDOT:PSS) is coated on the ITO layer by spin coating and dried.

A solution of which 10 mg of poly((4,8-bis(2-ethylhexyloxy)benzo(1,2-b:4,5-b′)dithiophene-2,6-diyl)(2-((2-ethylhexy loxy)carbonyl)-3-fluorothieno(3,4-b)thiophenediyl)) (PTB7) and 10 mg of C71-PCBM are dissolved in 1 ml of chlorobenzene is coated on the PEDOT:PSS layer and dried to provide a photoactive layer.

Then Ca and Al are sequentially thermal deposited on the photoactive layer at a deposition speed of about 5 Å/s.

Thereby, an organic solar cell is provided.

The obtained organic solar cell has a structure of ITO (150 nm)/PEDOT:PSS (30 nm)/PTB7:C71-PCBM (100 nm)/Ca (20 nm)/Al (100 nm).

### Comparative Example 2

### Manufacture of Organic Solar Cell

ITO is laminated on a glass substrate and cleansed with water/ultrasonic wave and using methanol and acetone, and treated with O₂ plasma and dried.

Then poly(3,4-ethylenedioxythiophene):poly(styrenesulfonate) (PEDOT:PSS) is coated on the ITO layer by spin coating and dried.

A solution of which 10 mg of poly((4,8-bis(octyloxy)benzo(1,2-b:4,5-b′)dithiophene-2,6-diyl)(2-((dodecyloxy)carbon yl)thieno(3,4-b)thiophenediyl)) (PTB1) and 10 mg of C71-PCBM are dissolved in 1 ml of chlorobenzene is coated on the PEDOT:PSS layer and dried to provide a photoactive layer.

Then Ca and Al are sequentially thermal-deposited on the photoactive layer at a deposition speed of about 5 Å/s.

Thereby, an organic solar cell is provided.

The obtained organic solar cell has a structure of ITO (150 nm)/PEDOT:PSS (30 nm)/PTB1:C71-PCBM (100 nm)/Ca (20 nm)/Al (100 nm).

### Experimental Example 1

### Evaluation of Light Absorption Wavelength and Emission Wavelength of Ultraviolet (UV) Absorber

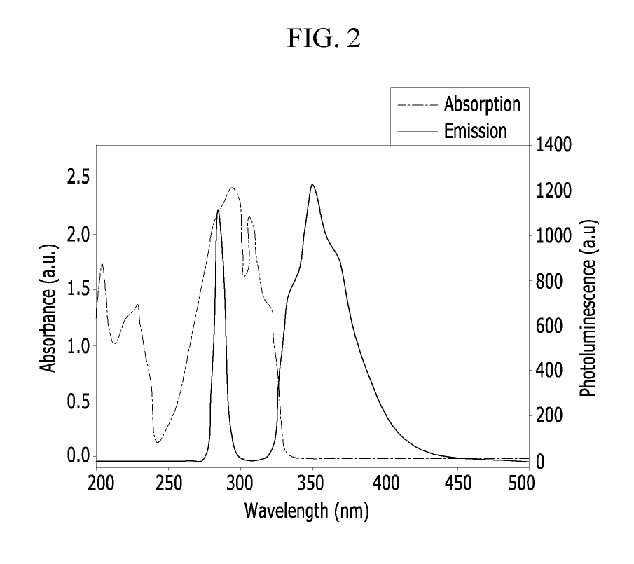

The compound represented by the above Chemical Formula 1-1 used in Examples 1 to 4 is measured for absorption wavelength using UV-Vis absorbance and measured for emission wavelength by photoluminescence (PL) with Cary 5000 (manufactured by Varian) equipment. The results are shown in FIG. 2.

As shown in FIG. 2, it is confirmed that the compound represented by the above Chemical Formula 1-1 absorbs light of about 200 nm to about 330 nm and shifts it into a long wavelength and emits light of about 320 nm to about 450 nm.

### Experimental Example 2

### Evaluation of Morphology of Photoactive Layer

10 mg of PTB7, 10 mg of C71-PCBM, and 0.6 mg of the compound represented by above Chemical Formula 1-1 are added to and mixed in chlorobenzene to provide a mixture as in Example 1.

Furthermore, 10 mg of PTB7 and 10 mg of C71-PCBM are added to and mixed in chlorobenzene to provide a mixture as in Comparative Example 1.

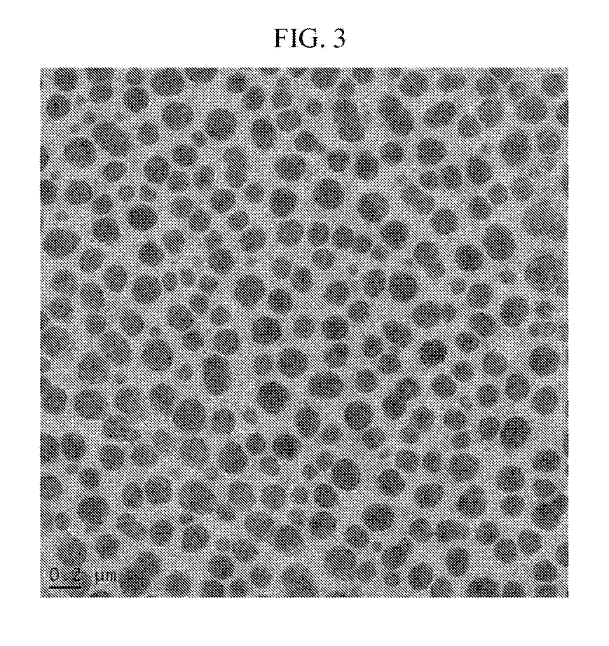

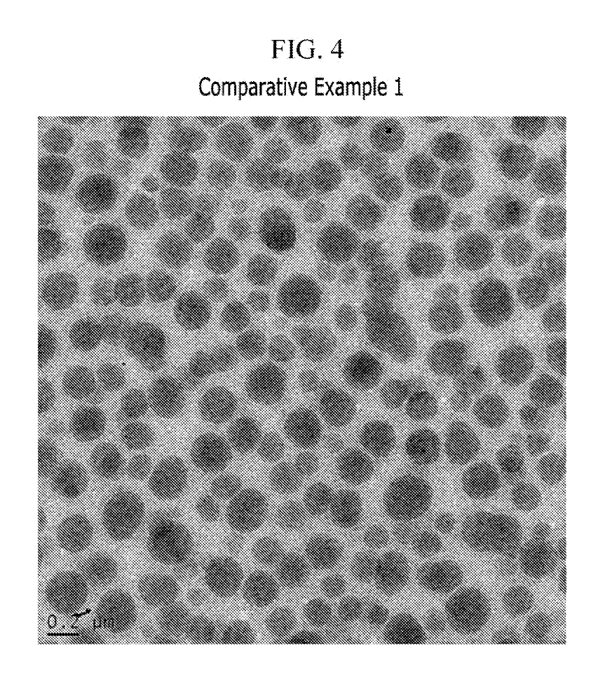

Each mixture is coated on a glass substrate by spin coating at a thickness of 100 nm to provide a photoactive layer. The photoactive layer is photographed with a transmission electron microscope (TEM) using Tecnai G2 F30 equipment. FIG. 3 shows a TEM image of the photoactive layer using the mixture obtained from Example 1, and FIG. 4 shows a TEM image of the photoactive layer using the mixture obtained from Comparative Example 1.

As shown in FIG. 3 and FIG. 4, since each separated domain is smaller and the photoactive materials, for example, PTB7 and C71-PCBM, are uniformly dispersed in the case of the photoactive layer using the mixture obtained from Example 1, it has much better morphology than the case of the photoactive layer using the mixture obtained from Comparative Example 1.

When PTB7 and C71-PCBM are uniformly dispersed in the photoactive layer as in Example 1, the contact surface area of the electron donor and electron acceptor is wider to increase the generated current and to improve the efficiency of the organic solar cell.

### Experimental Example 3

### Evaluation of Organic Solar Cell Efficiency

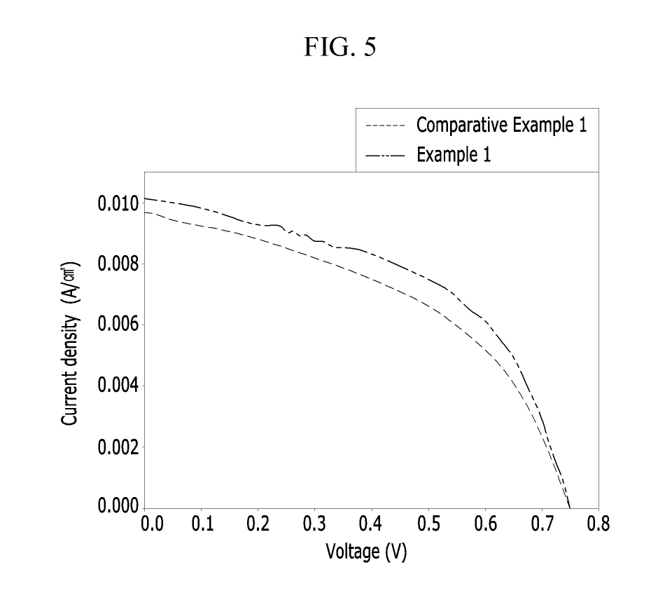

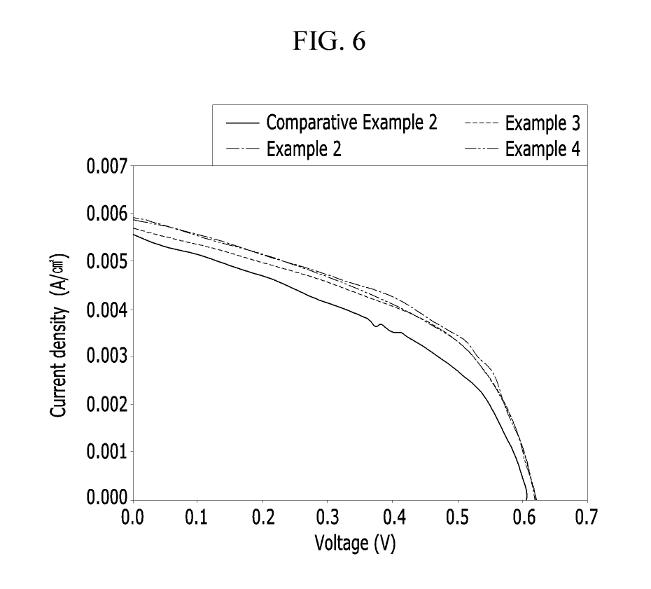

The solar cells obtained from Examples 1 to 4, Comparative Example 1, and Comparative Example 2 are measured for I-V curves using a customized (vertical beam direction) 300 W Solar Simulator (manufactured by Newport) and Keithley 2400 (manufactured by Keithley) equipment. FIG. 5 shows the results of Example 1 and Comparative Example 1, and FIG. 6 shows the results of Examples 2 and 3 and Comparative Example 2.

The open circuit voltage (V_{OC}), the short circuit current density (J_{SC}), the fill factor (FF), and the efficiency obtained from the I-V curves are shown in the following Table 1.

TABLE 1

| | Open circuit | Short circuit | | |
|---|---|---|---|---|
| | voltage | current density | | |
| | (V_{oc}) | (J_{sc}) | Fill factor (FF) | Efficiency |
| | (V) | (mA/cm²) | (%) | (%) |
| Example 1 | 0.75 | 10.1 | 50.5 | 3.8 |
| Comparative | 0.75 | 9.7 | 45.8 | 3.3 |
| Example 1 | | | | |
| Example 2 | 0.62 | 5.9 | 48.1 | 1.7 |
| Example 3 | 0.63 | 5.7 | 47.5 | 1.7 |
| Example 4 | 0.63 | 5.9 | 45.6 | 1.7 |
| Comparative | 0.61 | 5.5 | 43.2 | 1.5 |
| Example 2 | | | | |

As shown in Table 1 and FIG. 5, it is confirmed that the organic solar cell of Example 1 has much better short circuit current density, fill factor, and efficiency than the organic solar cell of Comparative Example 1.

In addition, as shown in Table 1 and FIG. 6, the organic solar cells according to Examples 2 to 4 have much better open circuit voltage, short circuit current density, fill factor, and efficiency than the organic solar cell according to Comparative Example 2.

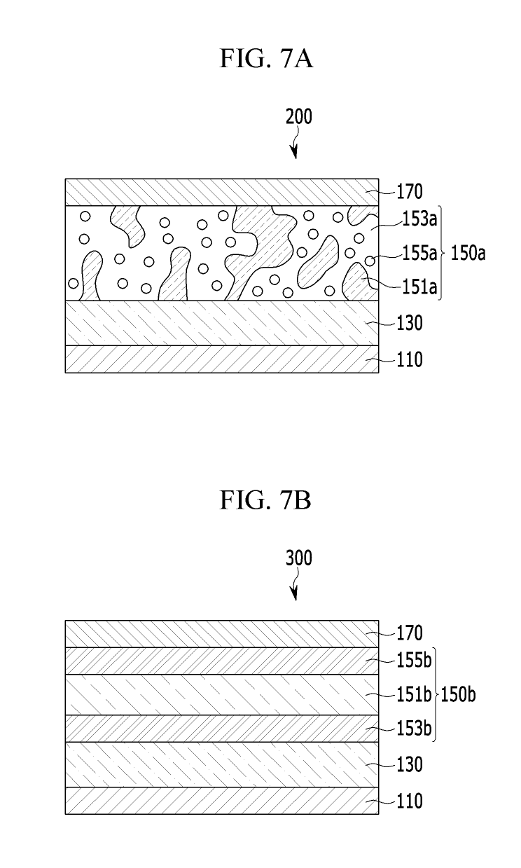

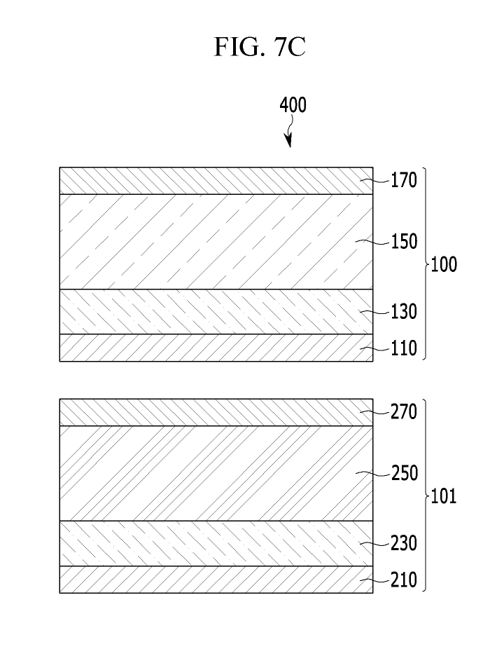

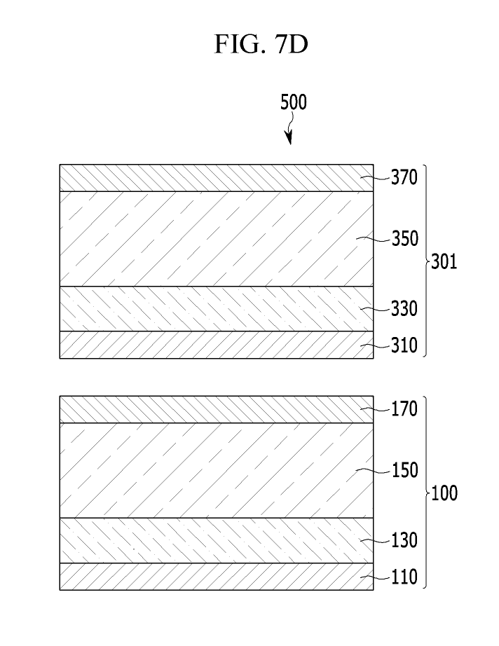

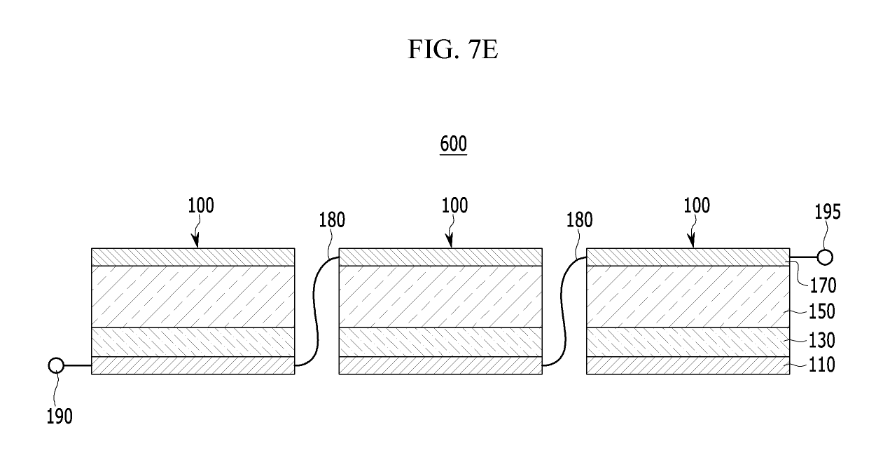

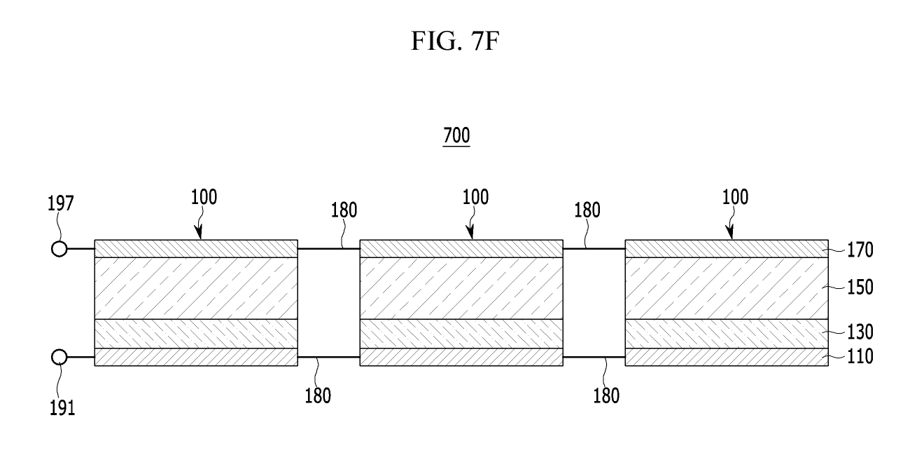

FIGS. 7A to 7D, respectively, show cross-sectional views of solar cells according to example embodiments. The description of like elements may be omitted to avoid duplication.

Referring to FIG. 7A, an organic solar cell 200 according to example embodiments may include a substrate 110, a lower electrode 130 on the substrate 110, a photoactive layer 150a on the lower electrode, and an upper electrode 170 on the photoactive layer 150a. The photoactive layer 150a may include a bulk heterojunction structure, in which a photoactive material contains a first semiconductor material 151a mixed with a second semiconductor material 153a, and an ultraviolet (UV) absorber 155a. The first organic semiconductor material 151a may include one of an electron acceptor containing an n-type semiconductor material and an electron donor containing a p-type semiconductor material. The second organic semiconductor material 153a may include the other of an electron acceptor containing an n-type semiconductor material and an electron donor containing a p-type semiconductor material.

Unless specified otherwise, the materials for the ultraviolet (UV) absorber 155a and the photoactive material containing the first semiconductor material 151a and the second semiconductor material 153a, respectively, may be the same materials as the ultraviolet (UV) absorber and the photoactive material, respectively, as described above with reference with FIG. 1.

Referring to FIG. 7B, an organic solar cell 300 according to example embodiments may include a substrate 110, a lower electrode 130 on the substrate 110, a photoactive layer 150b on the lower electrode, and an upper electrode 170 on the photoactive layer 150b. The photoactive layer 150b may include a bilayer structure, in which a photoactive material contains a first semiconductor material 151b on a second semiconductor material 153b, and an ultraviolet (UV) absorber 155b on the first semiconductor material 151b. The first organic semiconductor material 151b may include one of an electron acceptor containing an n-type semiconductor material and an electron donor containing a p-type semiconductor material. The second organic semiconductor material 153b may include the other of an electron acceptor containing an n-type semiconductor material and an electron donor containing a p-type semiconductor material.

Unless specified otherwise, the materials for the ultraviolet (UV) absorber 155b and the photoactive material containing the first semiconductor material 151b and the second semiconductor material 153b, respectively, may be the same materials as the ultraviolet (UV) absorber and the photoactive material, respectively, as described above with reference with FIG. 1.

Referring to FIG. 7C, an solar cell 400 according to example embodiments may include a multi-junction structure, in which the organic solar cell 100 of FIG. 1 is on another solar cell 101. The other solar cell 101 includes a substrate 210, a lower electrode 230, a photoactive layer 250, and an upper electrode 270. The organic solar cell 100 and the other solar cell 101 may be electrically connected to each other.

In the solar cell 400, both of the lower electrode 130 and the upper electrode 170 may include a transparent conductor, and the substrate 110 may be omitted, but example embodiments are not limited thereto.

Unless specified otherwise, the materials of the substrate 210, lower electrode 230, and upper electrode 270 may be the same materials as the substrate 110, lower electrode 130, and upper electrode 170, respectively, as described above with reference to FIG. 1. The photoactive layer 250 of the other solar cell 101 may include different materials than the photoactive layer 150 of the organic solar cell 100. For example, the photoactive layer 250 may contain materials that form a p-n junction that absorbs light and/or solar energy corresponding to a lower band gap than a band gap corresponding to the light and/or solar energy absorbed by the photoactive layer 150.

Referring to FIG. 7D, a solar cell 500 according to example embodiments may include a multi-junction structure, in which another solar cell 301 is on the organic solar cell 100 of FIG. 1. The other solar cell 301 includes a substrate 310, a lower electrode 330, a photoactive layer 350, and an upper electrode 370. The organic solar cell 100 and the other solar cell 301 may be electrically connected to each other.

In the solar cell 500, both of the lower electrode 330 and the upper electrode 370 may include a transparent conductor, and the substrate 310 may be omitted, but example embodiments are not limited thereto.

Unless specified otherwise, the materials of the substrate 310, lower electrode 330, and the upper electrode 370 may be the same materials as the substrate 110, lower electrode 130, and upper electrode 170, respectively, as described above with reference to FIG. 1. The photoactive layer 350 of the other solar cell 301 may include different materials than the photoactive layer 150 of the organic solar cell 100. For example, the photoactive layer 350 may contain materials that form a p-n junction that absorbs light and/or solar energy corresponding to a higher band gap than a band gap corresponding to the light and/or solar energy absorbed by the photoactive layer 150.

FIGS. 7E to 7F, respectively, show cross-sectional views of solar modules according to example embodiments.

Referring to FIG. 7E, a solar module 600 according to example embodiments may include two or more organic solar cells 100 electrically connected to each other in series by wires 180. The solar module 600 may include terminals 190 and 195 for withdrawing power from the solar module 600.

Referring to FIG. 7F, a solar module 700 according to example embodiments may include two or more organic solar cells 100 electrically connected to each other in parallel by wires 180. The solar module 700 may include terminals 191 and 197 for withdrawing power from the solar module 700.

While FIGS. 7E and 7F show two or more organic solar cells 100 electrically connected to each other in series and parallel, example embodiments are not limited thereto. One of ordinary skill in the art would appreciate that two or more organic solar cells may be electrically connected in series, parallel, and series-parallel in order to achieve the desired power output. Alternatively, two or more of the foregoing organic solar cells 200, organic solar cells 300, solar cell 400, and solar cells 500 may be electrically connected to each other in order to achieve the desired power output.

While some example embodiments have been particularly shown and described, it will be understood by one of ordinary skill in the art that variations in form and detail may be made therein without departing from the spirit and scope of the claims.

What is claimed is:

1. An organic solar cell, comprising:
a first electrode;
a second electrode on the first electrode; and
a photoactive layer between the first electrode and the second electrode, the photoactive layer including a photoactive material and an ultraviolet (UV) absorber.

2. The organic solar cell of claim 1, wherein
the ultraviolet (UV) absorber absorbs light having a wavelength range of about 100 nm to about 400 nm, and
the ultraviolet (UV) absorber emits light having a wavelength range of about 150 nm to about 500 nm.

3. The organic solar cell of claim 2, wherein
the ultraviolet (UV) absorber absorbs light having a wavelength range of about 200 nm to about 330 nm, and
the ultraviolet (UV) absorber emits light having a wavelength range of about 320 nm to about 450 nm.

4. The organic solar cell of claim 3, wherein
the ultraviolet (UV) absorber absorbs light having a wavelength range of about 250 nm to about 325 nm, and
the ultraviolet (UV) absorber emits light having a wavelength range of about 320 nm to about 450 nm.

5. The organic solar cell of claim 1, wherein the ultraviolet (UV) absorber comprises a compound represented by the following Chemical Formula 1: 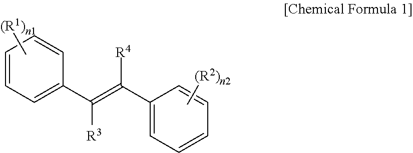
wherein, in Chemical Formula 1,
R¹ to R⁴ are the same or different, and are each independently one of a hydrogen, a substituted or unsubstituted C1 to C30 alkyl group, a substituted or unsubstituted C3 to C30 cycloalkyl group, and a substituted or unsubstituted C2 to C30 heterocycloalkyl group, and
n1 and n2 are each independently an integer ranging from 0 to 5.

6. The organic solar cell of claim 5,
wherein in Chemical Formula 1,
R¹ to R⁴ are the same or different, and are each independently one of a hydrogen, a substituted or unsubstituted C1 to C10 alkyl group, a substituted or unsubstituted C3 to C10 cycloalkyl group, and a substituted or unsubstituted C2 to C10 heterocycloalkyl group.

7. The organic solar cell of claim 5, wherein the ultraviolet (UV) absorber comprises a compound represented by the following Chemical Formula 1-1:

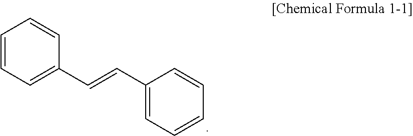 [SMILES: C(=C\c1ccccc1)/c1ccccc1]

8. The organic solar cell of claim 1, wherein the photoactive layer contains about 0.01 parts by weight to about 30 parts by weight of the ultraviolet (UV) absorber, based on 100 parts by weight of the photoactive material.

9. The organic solar cell of claim 8, wherein the photoactive layer contains about 0.1 parts by weight to about 10 parts by weight of the ultraviolet (UV) absorber, based on 100 parts by weight of the photoactive material.

10. The organic solar cell of claim 1, wherein the photoactive layer includes a bulk heterojunction (BHJ) structure.

11. The organic solar cell of claim 1, wherein the photoactive material comprises:
a p-type semiconductor material, and
an n-type semiconductor material.

12. The organic solar cell of claim 1, wherein the photoactive material comprises:
at least two of polyaniline, polypyrrole, polythiophene, poly(p-phenylenevinylene), poly(2-methoxy-5-(2′-ethyl-hexyloxy)-1,4-phenylene vinylene) (MEH-PPV), poly(2-methoxy-5-(3,7-dimethyloctyloxy)-1,4-phenylene-vinylene) (MDMO-PPV), pentacene, poly(3,4-ethylenedioxythiophene) (PEDOT), poly(3-alkylthiophene), poly((4,8-bis(octyloxy)benzo(1,2-b:4,5-b′)dithiophene-2,6-diyl)(2-((dodecyloxy)carbon yl)thieno(3,4-b)thiophenediyl)) (PTB1), poly((4,8-bis(2-ethylhexyloxy)benzo(1,2-b:4,5-b′)dithiophene-2,6-diyl)(2-((2-ethylhexy loxy)carbonyl)-3-fluorothieno(3,4-b)thiophenediyl)) (PTB7), phthalocyanine, tin (II) phthalocyanine (SnPc), copper phthalocyanine, triarylamine, bezidine, pyrazoline, styrylamine, hydrazone, carbazole, thiophene, 3,4-ethylenedioxythiophene (EDOT), pyrrole, phenanthrene, tetracene, naphthalene, rubrene, 1,4,5,8-naphthalene-tetracarboxylic dianhydride (NTCDA), Alq₃, fullerene (C60, C70, C74, C76, C78, C82, C84, C720, C860, or a combination thereof), 1-(3-methoxy-carbonyl)propyl-1-phenyl(6,6)C61 (PCBM), C71-PCBM, C84-PCBM, bis-PCBM, perylene, CdS, CdTe, CdSe, ZnO, a derivative thereof, and a combination thereof.

13. The organic solar cell of claim 1, wherein a solvent for providing the photoactive layer comprises one selected from deionized water, methanol, ethanol, propanol, 1-butanol, isopropanol, 2-methoxyethanol, 2-ethoxyethanol, 2-propoxyethanol 2-butoxyethanol, methylcellosolve, ethylcellosolve, diethylene glycol methylether, diethylene glycol ethylether, dipropylene glycol methylether, toluene, xylene, hexane, heptane, octane, ethylacetate, butylacetate, diethylene glycol dimethylether, diethylene glycol dimethylethylether, methylmethoxy propionate, ethylethoxy propionate, ethyl lactate, propylene glycol methyletheracetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide(DMF), N,N-dimethyl acetamide(DMAc), N-methyl-2-pyrrolidone, γ-butyrolactone, diethylether, ethylene glycol dimethylether, diglyme, tetrahydrofuran, chlorobenzene, dichlorobenzene, acetylacetone, acetonitrile, bromobenzene, 1-chloronaphthalene, fluorobenzene, 1,2,4-trichlorobenzene, 2-bromothiophene, benzaldehyde, acetophenone, ethylene dichloride, 1,1,2,2-tetrachloroethane, iodobenzene, 1-bromonaphthalene, nitrobenzene, pyridine, di-(2-chloroethyl)ether, benzyl acetate, cyclohexyl chloride, tetrahydronaphthalene, 1-iodonaphthalene, cyclohexanone, 1,1,2-trichloroethane, trichloroethylene, 2-chlorothiophene, 1,1,1-trichloroethane, styrene, diethyl sulfide, methylene diiodide, 1,1,2,2-tetrabromoethane, 1-chlorobutane, ethyl benzene, butanethiol, benzene, thiophene, methylene dichloride, 1,4-dioxane, cyclohexylamine, furan, carbon tetrachloride, tetrahydrofuran, N-methylpyrrolidine, methyl ethyl ketone, methyl isobutyl ketone, cyclohexane, 2-nitropropane, and a combination thereof.

14. The organic solar cell of claim 1, wherein the photoactive material and the ultraviolet (UV) absorber have a radius of interaction (Rₐ) of about 7 or less.

15. The organic solar cell of claim 14, wherein the photoactive material and the ultraviolet (UV) absorber have a radius of interaction (Rₐ) of about 5 or less.

16. The organic solar cell of claim 1,
wherein the photoactive material includes C71-PCBM and one of PTB1 and PTB7; and
wherein the ultraviolet (UV) absorber comprises a compound represented by the following Chemical Formula 1: 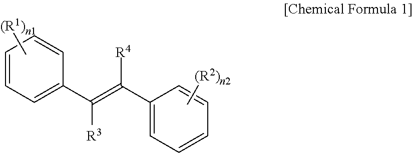
wherein, in Chemical Formula 1,
R¹ to R⁴ are the same or different, and are each independently one of a hydrogen, a substituted or unsubstituted C1 to C30 alkyl group, a substituted or unsubstituted C3 to C30 cycloalkyl group, and a substituted or unsubstituted C2 to C30 heterocycloalkyl group, and
n1 and n2 are each independently an integer ranging from 0 to 5.

17. The organic solar cell of claim 1, further comprising:
at least one of an electron transporting layer (ETL) and a hole transporting layer (HTL) between the photoactive layer and one of the first electrode and the second electrode; and
wherein the ultraviolet (UV) absorber comprises a compound represented by the following Chemical Formula 1: 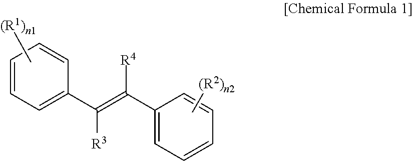
wherein, in Chemical Formula 1,
R¹ to R⁴ are the same or different, and are each independently one of a hydrogen, a substituted or unsubstituted C1 to C30 alkyl group, a substituted or unsubstituted C3 to C30 cycloalkyl group, and a substituted or unsubstituted C2 to C30 heterocycloalkyl group, and
n1 and n2 are each independently an integer ranging from 0 to 5.

18. The organic solar cell of claim 17, wherein
the photoactive layer includes one of a bi-layer structure, a multi-junction structure, and a bulk heterojunction structure.

19. An organic solar cell module, comprising:
a plurality of the organic solar cells according to claim 18,
wherein the organic solar cells are electrically connected to each other in one of series, parallel, and series-parallel.

20. A method of manufacturing an organic solar cell, comprising:
forming a photoactive layer on one surface of a first electrode,
the photoactive layer including a photoactive material and an ultraviolet (UV) absorber; and
forming a second electrode on the photoactive layer.

21. The method of claim 20, wherein the forming a photoactive layer comprises:
mixing a photoactive material, an ultraviolet (UV) absorber, and a solvent to provide a mixture, and
coating the mixture on the one surface of the first electrode.

22. The method of claim 21, wherein the solvent includes at least one of deionized water, methanol, ethanol, propanol, 1-butanol, isopropanol, 2-methoxyethanol, 2-ethoxyethanol, 2-propoxyethanol 2-butoxyethanol, methylcellosolve, ethylcellosolve, diethylene glycol methylether, diethylene glycol ethylether, dipropylene glycol methylether, toluene, xylene, hexane, heptane, octane, ethylacetate, butylacetate, diethylene glycol dimethylether, diethylene glycol dimethylethylether, methylmethoxy propionate, ethylethoxy propionate, ethyl lactate, propylene glycol methyletheracetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide (DMF), N,N-dimethyl acetamide DMAc), N-methyl-2-pyrrolidone, γ-butyrolactone, diethylether, ethylene glycol dimethylether, diglyme, tetrahydrofuran, chlorobenzene, dichlorobenzene, acetylacetone, acetonitrile, bromobenzene, 1-chloronaphthalene, fluorobenzene, 1,2,4-trichlorobenzene, 2-bromothiophene, benzaldehyde, acetophenone, ethylene dichloride, 1,1,2,2-tetrachloroethane, iodobenzene, 1-bromonaphthalene, nitrobenzene, pyridine, di-(2-chloroethyl)ether, benzyl acetate, cyclohexyl chloride, tetrahydronaphthalene, 1-iodonaphthalene, cyclohexanone, 1,1,2-trichloroethane, trichloroethylene, 2-chlorothiophene, 1,1,1-trichloroethane, styrene, diethyl sulfide, methylene diiodide, 1,1,2,2-tetrabromoethane, 1-chlorobutane, ethyl benzene, butanethiol, benzene, thiophene, methylene dichloride, 1,4-dioxane, cyclohexylamine, furan, carbon tetrachloride, tetrahydrofuran, N-methylpyrrolidine, methyl ethyl ketone, methyl isobutyl ketone, cyclohexane, 2-nitropropane, and a combination thereof.

23. A method of claim 21, wherein the photoactive material and the ultraviolet (UV) absorber have a radius of interaction (Rₐ) of about 7 or less.

24. The organic solar cell of claim 20, wherein the ultraviolet (UV) absorber comprises a compound represented by the following Chemical Formula 1: 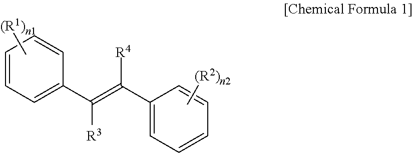
wherein, in Chemical Formula 1,
R¹ to R⁴ are the same or different, and are each independently one of a hydrogen, a substituted or unsubstituted C1 to C30 alkyl group, a substituted or unsubstituted C3 to C30 cycloalkyl group, and a substituted or unsubstituted C2 to C30 heterocycloalkyl group, and
n1 and n2 are each independently an integer ranging from 0 to 5.

25. The organic solar cell of claim 20, wherein the ultraviolet (UV) absorber comprises a compound represented by the following Chemical Formula 1-1: 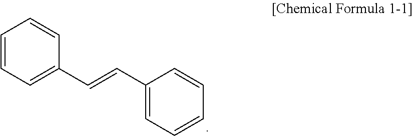 [SMILES: C(=C\c1ccccc1)/c1ccccc1]
